(19) United States
(12) Patent Application Publication
(10) Pub. No.: US 2025/0379568 A1
(43) Pub. Date: Dec. 11, 2025

(54) DEVICES AND TECHNIQUES TO MODIFY A CLOCK SIGNAL

(71) Applicant: Micron Technology, Inc., Boise, ID (US)

(72) Inventors: Maksim Kuzmenka, München (DE); Miljana Nenadovic, München (DE)

(21) Appl. No.: 19/213,540

(22) Filed: May 20, 2025

Related U.S. Application Data
(60) Provisional application No. 63/658,595, filed on Jun. 11, 2024.

(51) Int. Cl. H03K 5/135; H03K 5/00

(52) U.S. Cl. CPC H03K 5/135; H03K 2005/00019

(57) ABSTRACT

Methods, systems, and devices for devices and techniques to modify a clock signal are described. A memory system may include a delay adjustment circuit coupled with a clock signal path to compensate for changes in the delay of a clock signal due to fluctuations in a supply voltage. The delay adjustment circuit may include a current mirror, a first compensation component coupled with the clock signal path, and a second compensation component coupled with the clock signal path. The current mirror may be configured to output, based on the supply voltage, a first control signal to the first compensation component and a second control signal to the second compensation component. The compensation components may be configured to modify the clock signal along the clock signal path based on the received control signals.

### CROSS REFERENCE

The present application for patent claims priority to U.S. Patent Application No. 63/658,595 by Kuzmenka et al., entitled “DEVICES AND TECHNIQUES TO MODIFY A CLOCK SIGNAL,” filed Jun. 11, 2024, which is assigned to the assignee hereof, and which is expressly incorporated by reference in its entirety herein.

### TECHNICAL FIELD

The following relates to one or more systems for memory, including devices and techniques to modify a clock signal.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports devices and techniques to modify a clock signal in accordance with examples as disclosed herein.

FIG. 2 shows an example of a circuit that supports devices and techniques to modify a clock signal in accordance with examples as disclosed herein.

FIG. 3 shows an example of a timing diagram that supports devices and techniques to modify a clock signal in accordance with examples as disclosed herein.

FIG. 4 shows an example of a circuit that supports devices and techniques to modify a clock signal in accordance with examples as disclosed herein.

FIG. 5 shows an example of a system that supports devices and techniques to modify a clock signal in accordance with examples as disclosed herein.

FIG. 6 shows a block diagram of a memory system that supports devices and techniques to modify a clock signal in accordance with examples as disclosed herein.

FIG. 7 shows a flowchart illustrating a method or methods that support devices and techniques to modify a clock signal in accordance with examples as disclosed herein.

### DETAILED DESCRIPTION

In some systems, a memory system may operate according to an external clock signal. For example, a memory system may receive a clock system from a host system, and the memory system may utilize the received clock signal for various operations. In some cases, the memory system may include a clock signal path, such as a clock tree, to route a received clock signal to one or more components that may use the clock signal to extract data from data signals transmitted by the host system. In some cases, the clock signal path may be relatively long (e.g., several hundred microns), and may include components to support propagating the clock signal along the clock signal path. Such components, as well as the length of the clock signal path, may introduce delay into the clock signal (between reception of the clock signal and the eventual components that use the clock signal). To account for such delays, some memory systems may be “trained” to realign the clock signal (at the components using the clock signal) with the received clock signal. For example, a controller may add a delay to the clock signal, the data signals, or both to realign the clock signals and the data signals (e.g., may “trim” the clock signal, the data signals, or both). Alternatively, a memory system may include a phase-locked loop (PLL) or delay-locked loop (DLL) to compensate for the delay. However, such methods may be relatively complex and time consuming. Further, in some cases, the delay of the clock signal may change in response to changes in temperature, supply voltage, or both, which may add further complexity.

As described herein, a memory system may include a delay adjustment circuit coupled with a clock signal path to compensate for changes in the delay of a clock signal due to fluctuations in a supply voltage. The delay adjustment circuit may include a current mirror, a first compensation component coupled with the clock signal path, and a second compensation component coupled with the clock signal path. The current mirror may be configured to output, based on the supply voltage, a first control signal to the first compensation component and a second control signal to the second compensation component. The compensation components may be configured to modify the clock signal along the clock signal path based on the received control signals. Such modifications may reduce the change in the delay of the clock signal in response to fluctuations in the supply voltage, which may improve the ability of the memory system to extract data from received data signals.

In addition to applicability in memory systems as described herein, techniques and devices for modifying a clock signal may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving trimming of clock signals of a memory system, which may improve the ability of the memory system to extract data from data signals transmitted by a host system, and thus decrease processing or latency times, improve response times, or otherwise improve user experience, among other benefits.

Features of the disclosure are illustrated and described in the context of systems and architectures. Features of the disclosure are further illustrated and described in the context of circuits, timing diagrams, and flowcharts.

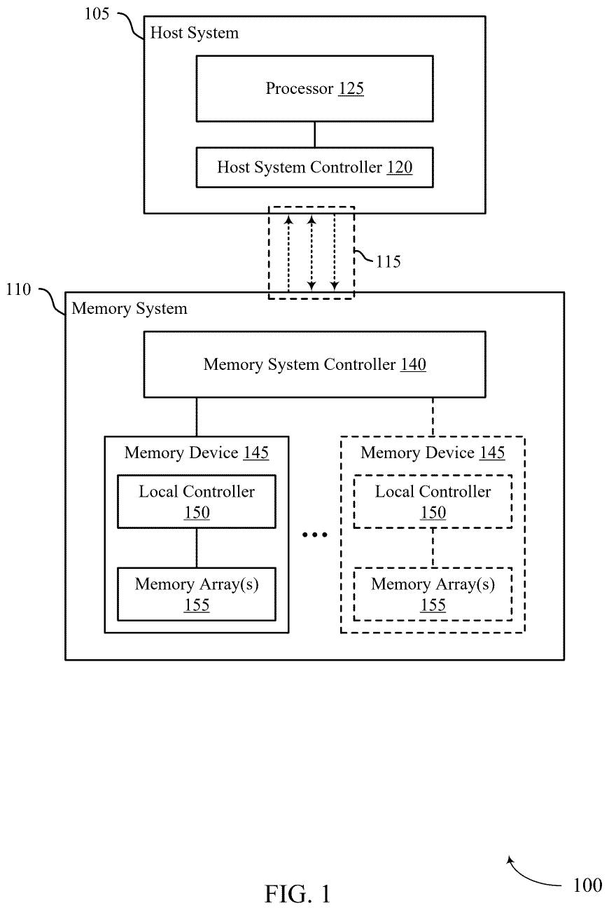

FIG. 1 illustrates an example of a system 100 that supports devices and techniques to modify a clock signal in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

Signaling may be communicated over the channels 115 using single data rate (SDR) signaling or double data rate (DDR) signaling, among other rates (e.g., relative to a clock signal). In SDR signaling, one modulation symbol (e.g., signal level) of a signal may be registered for each clock cycle (e.g., on a rising edge or a falling edge of a clock signal). In DDR signaling, two modulation symbols of a signal may be registered for each clock cycle (e.g., on both a rising edge and a falling edge of a clock signal).

In some cases, a memory system 110 may include a delay adjustment circuit coupled with a clock signal path to compensate for changes in the delay of a clock signal due to fluctuations in a supply voltage. The delay adjustment circuit may include a current mirror, a first compensation component coupled with the clock signal path, and a second compensation component coupled with the clock signal path. The current mirror may be configured to output, based on the supply voltage, a first control signal to the first compensation component and a second control signal to the second compensation component. The compensation components may be configured to modify the clock signal along the clock signal path based on the received control signals. Such modifications may reduce the change in the delay of the clock signal in response to fluctuations in the supply voltage, which may improve the ability of the memory system 110 to extract data from received data signals.

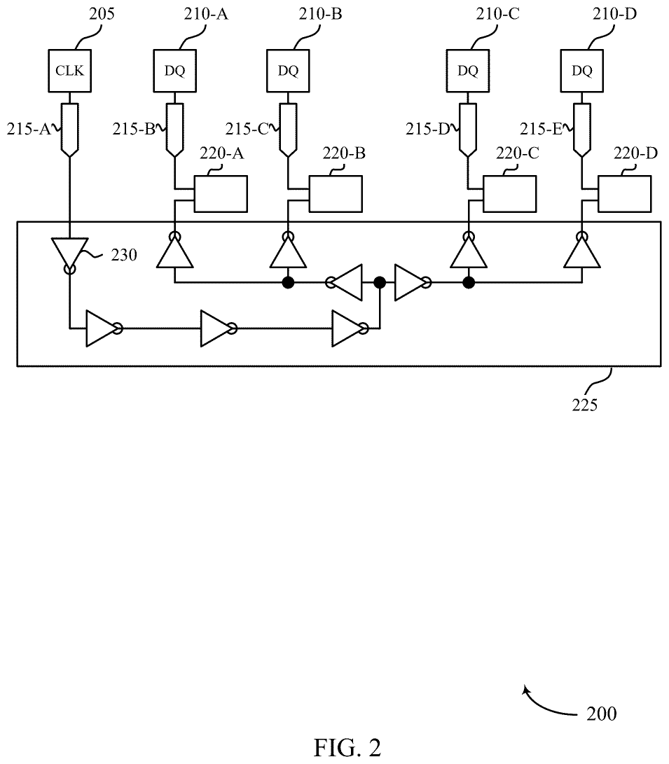

FIG. 2 shows an example of a circuit 200 that supports devices and techniques to modify a clock signal in accordance with examples as disclosed herein. The circuit 200 may be implemented in at least a portion of a memory system 110, such as an interface between a host system 105 and memory system 110. For example, the circuit 200 may include one or more channels, such as a clock signal channel 205 and one or more data channels 210 (e.g., a data channel 210-a, a data channel 210-b, a data channel 210-c, and a data channel 210-d), that may be examples of the channels 115 as described with reference to FIG. 1.

In some cases, the clock signal channel 205 and the data channel 210 may communicate signals between the host system 105 and the memory system 110. For example, the host system 105 may provide a clock signal to the memory system 110 via the clock signal channel 205 and may transmit data to the memory system 110 via the data channels 210. The memory system may, via a receivers 215-a, receive the clock signal and, via the receivers 215-b, 215-c, 215-d, and 215-c, receive data signals, and may use the clock signal to interpret the data signals. For example, the memory system 110 may include a clock signal path 225 (e.g., a clock tree) that may route the clock signal to one or more samplers 220 coupled respectively with the data channels 210. The samplers 220 (e.g., a sampler 220-a coupled with the receiver 215-b, a sampler 220-b coupled with the receiver 215-c, a sampler 220-c coupled with the receiver 215-d, and a sampler 220-d coupled with the receiver 215-e) may use the clock signal to extract data from the data signals. For example, a sampler 220 may use the clock signal as a reference signal, and may sample a data signal according to the clock signal (e.g., at a rising edge of the clock signal, at a falling edge of the clock signal, or both).

In some examples, the clock signal path 225 may propagate the clock signal to the samplers 220 over a relatively long signal path (e.g., several hundred microns). To support such propagation, the clock signal path 225 may include one or more components 230, such as inverters (e.g., complementary metal-oxide semiconductor (CMOS) inverters, re-drivers) or other CMOS gates (e.g., frequency dividers, multiplexers, trimmable delay cells, or the like). Such components 230 may delay the clock signal, which may cause a misalignment between the clock signal received by each sampler 220 and the respective data signal received by each sampler 220.

To account for such delays, the circuit 200 may be “trained” to realign the clock signal with the data signals. For example, a controller of a memory system 110 (e.g., the memory system controller 140) may add a delay to the clock signal, the data signals, or both to realign the clock signals and the data signals (e.g., may “trim” the clock signal, the data signals, or both). Alternatively, a memory system 110 may include a (PLL) or (DLL) to compensate for the delay, may add components to the data channels 210 to match the delay of the components 230. However, such methods may be relatively complex and time consuming. Further, in some cases, the delay of the clock signal may change in response to changes in temperature, supply voltage, or both, which may add further complexity. Additionally, or alternatively, a memory system 110 may include relatively low voltage transistors along the clock signal path 225, which may reduce the sensitivity of the delay to changes in supply voltage, but may introduce high leakage currents.

As described herein, the clock signal path 225 may be coupled with a delay adjustment circuit to compensate for changes in the delay of a clock signal due to fluctuations in a supply voltage. The delay adjustment circuit may include a current mirror, a first compensation component coupled with the clock signal path 225, and a second compensation component coupled with the clock signal path 225. The current mirror may be configured to output, based on the supply voltage, a first control signal to the first compensation component and a second control signal to the second compensation component. The compensation components may be configured to modify the clock signal along the clock signal path 225 based on the received control signals. Such modifications may reduce the change in the delay of the clock signal in response to fluctuations in the supply voltage, which may improve the ability of the memory system to extract data from received data signals.

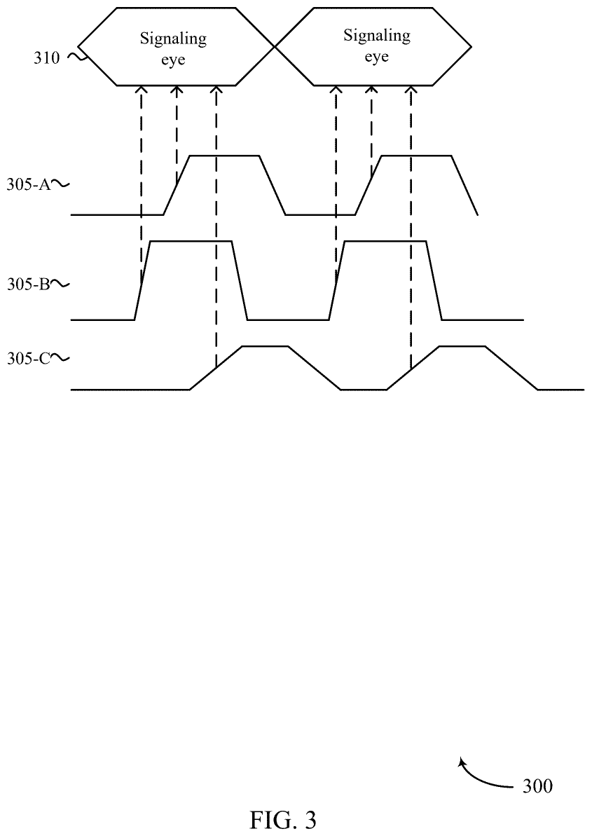

FIG. 3 shows an example of a timing diagram 300 that supports devices and techniques to modify a clock signal in accordance with examples as disclosed herein. The timing diagram 300 may illustrate timing aspects of one or more clock signals 305 (e.g., a voltage over time of clock signals 305) received by a sampler 220 and a data signal 310 received by the sampler 220. In some cases, delay of a clock signal, which may correspond to a difference in phase between the clock signal at a first point along clock signal path (e.g., at a receiver 215) and the clock signal at a second point along the clock signal path (e.g., at a sampler 220) may be affected by multiple factors, such as a delay caused by transistors or other components along the clock signal path, temperature along the clock signal path, and the supply voltage associated with the clock signal path. Some factors, such as delay caused by transistors, may be accounted for by trimming the clock signal 305, trimming the data signal 310, or both. Further, changes in delay caused by a change in temperature may be relatively slow and relatively small.

However, changes in the supply voltage associated with a clock signal path may cause relatively large unpredictable delays. For example, the clock signal 305-a may correspond to a first voltage (e.g., 1.2 volts), the clock signal 305-b may correspond to a second voltage (e.g., 1.3 volts), and the clock signal 305-c may correspond to a third voltage (e.g., 1.1 volts). As illustrated in FIG. 3, relatively small fluctuations in the supply voltage (e.g., an increase or decrease of around 100 millivolts) may result in relatively large changes to a clock signal 305 (e.g., a shift of around 40 picoseconds), which may reduce the ability of a sampler to reliably extract data from a data signal 310.

To reduce changes in delay caused by fluctuations in supply voltage, a memory system may include a delay adjustment circuit coupled with a clock signal path to compensate for changes in the delay of a clock signal due to fluctuations in a supply voltage. The delay adjustment circuit may include a current mirror, a first compensation component coupled with the clock signal path, and a second compensation component coupled with the clock signal path. The current mirror may be configured to output, based on the supply voltage, a first control signal to the first compensation component and a second control signal to the second compensation component. The compensation components may be configured to modify the clock signal along the clock signal path based on the received control signals. Such modifications may reduce the change in the delay of the clock signal in response to fluctuations in the supply voltage, which may improve the ability of the memory system to extract data from received data signals.

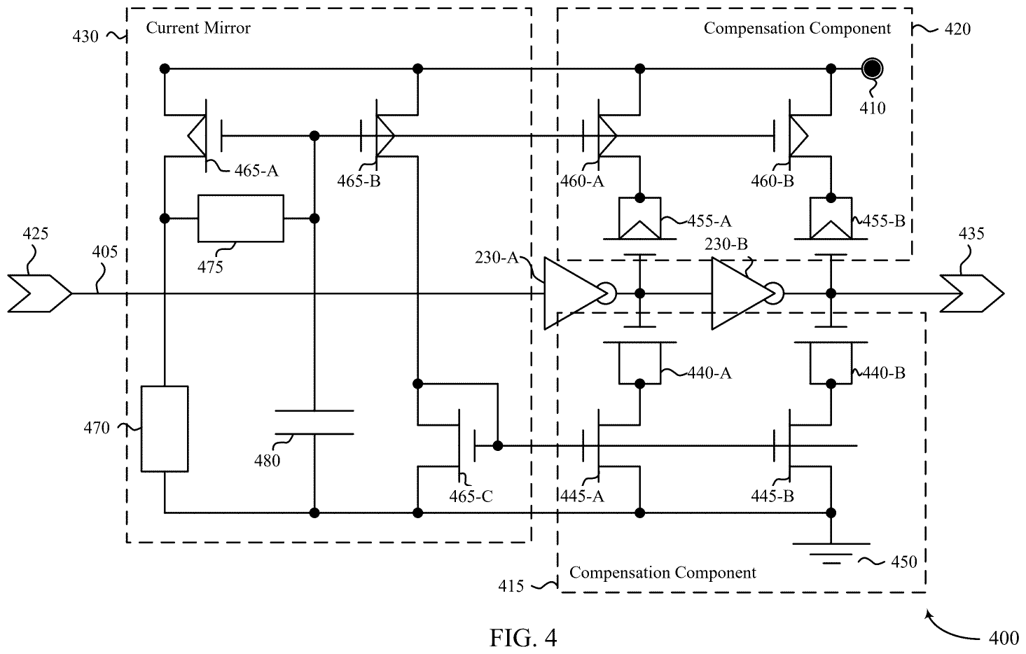

FIG. 4 shows an example of a circuit 400 that supports devices and techniques to modify a clock signal in accordance with examples as disclosed herein. The circuit 400 may be an example of a clock signal path 405 implemented in a memory system, which may include aspects of the clock signal path 225 as described with reference to FIG. 2. In some cases, delay associated with components 230 (e.g., components 230-a and 230-b) may have a negative linear relationship with a supply voltage of the supply voltage source 410. For example, if the supply voltage increases, the delay associated with the components 230 may decrease. Such a change in delay of a clock signal may introduce complexities in accounting for the delay, as described herein. To mitigate changes in the delay of the clock signal resulting from changes in the supply voltage, the circuit 400 may include a compensation component 415 and a compensation component 420 coupled with the clock signal path 405. The compensation components 415 and 420 may have a positive relationship with the supply voltage. For example, if the supply voltage increases, the delay associated with the compensation components 415 and 420 may increase.

For example, a receiver 425 of the clock signal path 405 may receive a clock signal (e.g., a clock signal provided by a host system 105). As the clock signal propagates through the components 230 along the clock signal path, the compensation components 415 and 420 may modify the clock signal based on control signals received from a current mirror 430. A transmitter 435 of the clock signal path may transmit the modified clock signal, such as by outputting the modified clock signal to one or more components of the memory system (e.g., to samplers 220). Accordingly, by coupling the compensation components 415 and 420 with the clock signal path 405, the change in delay of the clock signal resulting from changes in the supply voltage may be reduced, which may improve the ability of the memory system to effectively and efficiently account for delays in the clock signal.

The compensation component 415 may include a set of capacitors 440 (e.g., a capacitor 440-a and a capacitor 440-b) coupled with the clock signal path 405. In some cases, the capacitors 440 may be examples of n-type metal-oxide semiconductor (nMOS) capacitors, and the delay added to the clock signal by the capacitors 440 may have a positive relationship with the supply voltage. For example, the capacitance of a capacitor 440 may be approximately linear with respect to voltage across plates of the capacitor, which may result in a positive relationship between added delay and the supply voltage, as well as mitigate clock duty-cycle distortions. In some examples, the capacitors 440 may be implemented using nMOS transistors operated in a triode regime, as illustrated in FIG. 4. Additionally, or alternatively, the capacitors may be implemented using other circuit components, such as metal-insulator-metal (MIM) capacitors.

The compensation component 415 may further include a set of transistors 445 coupled with the capacitors 440, including: a transistor 445-a having a first terminal coupled with the capacitor 440-a and a second terminal coupled with a ground voltage source 450; and a transistor 445-b having a first terminal coupled with the capacitor 440-b and a second terminal coupled with the ground voltage source 450. Each transistor 445 may also include a respective gate coupled with the current mirror 430. A transistor 445 may be operated in triode mode, and accordingly may be an example of a variable resistor. For example, the resistance of a transistor 445 may depend on the voltage applied to the gate. Accordingly, the resistance of the transistors 445 may be determined by the strength of a first control signal output by the current mirror 430. Thus, the delay added to the clock signal by the capacitors 440 may similarly be determined by the first control signal.

The compensation component 420 may include a set of capacitors 455 (e.g., a capacitor 455-a and a capacitor 455-b) coupled with the clock signal path 405. In some cases, the capacitors 455 may be examples of p-type MOS capacitors, and the delay added to the clock signal by the capacitors 455 may have a positive relationship with the supply voltage. For example, the capacitance of a capacitor 455 may be approximately linear with respect to voltage across plates of the capacitor, which may result in a positive relationship between added delay and the supply voltage, as well as mitigate clock duty-cycle distortions. In some examples, the capacitors 455 may be implemented using pMOS transistors operated in a triode regime, as illustrated in FIG. 4. Additionally, or alternatively, the capacitors may be implemented using other circuit components, such as MIM capacitors.

The compensation component 415 may further include a set of transistors 460 coupled with the capacitors 455, including: a transistor 460-a having a first terminal coupled with the capacitor 455-a and a second terminal coupled with the supply voltage source 410; and a transistor 460-b having a first terminal coupled with the capacitor 455-b and a second terminal coupled with the supply voltage source 410. Each transistor 460 may also include a respective gate coupled with the current mirror 430. A transistor 460 may be operated in triode mode, and accordingly may be an example of a variable resistor. For example, the resistance of a transistor 460 may depend on the voltage applied to the gate. Accordingly, the resistance of the transistors 460 may be determined by the strength of a second control signal output by the current mirror 430. Thus, the delay added to the clock signal by the capacitors 455 may similarly be determined by the second control signal.

The current mirror 430 may include a transistor 465-a, a transistor 465-b, and a transistor 465-c. The transistor 465-b may be configured to mirror current associated with the transistor 465-a to the transistor 465-b. The transistor 465-a may be diode connected, and may support outputting the second control signal to the compensation component 420. Similarly, the transistor 465-c may be diode connected, and may support outputting the first control signal to the compensation component 415. By way of example, an increase in the supply voltage may result in an increased current through the current mirror 430, which may in turn reduce the resistance of the transistors 445 and 460, leading to an increase in the delay added by the compensation components 415 and 420.

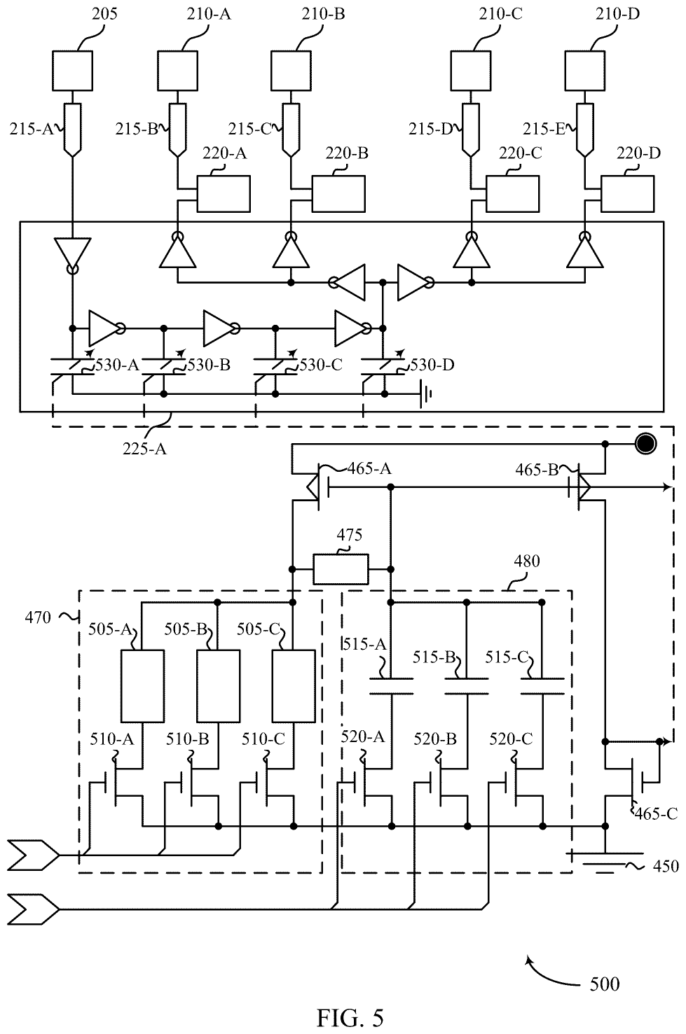

In some cases, current through the current mirror 430 may include additional components to support managing the first control signal and the second control signal. For example, the current mirror 430 may include a variable resistor component 470. Further, the current mirror 430 may include a resistor 475 and a variable capacitor component 480. In some examples, the resistor 475 and the variable capacitor component 480 may act as a filter and may account for periodic variations in the supply voltage. By configuring the resistance of the variable resistor component 470 (e.g., as described in further detail with reference to FIG. 5), the current delivered to the current mirror 430 may be managed. Further, by configuring parameters of the resistor 475 and the variable capacitor component 480 (e.g., the resistance of the resistor 475 divided by the capacitance of the variable capacitor component 480, as described in further detail with reference to FIG. 5), a frequency range of compensation may be managed. Although FIG. 4 includes a resistor 475 and a variable capacitor component 480 configured as a filter, other filter components may be included or used, such as a pass band filter tuned to the frequency of the supply voltage.

FIG. 5 shows an example of a system 500 that supports devices and techniques to modify a clock signal in accordance with examples as disclosed herein. The system 500 may include clock signal path 225-a coupled with compensation components 530 (e.g., compensation components 530-a, 530-b, 530-c, and 530-d). A compensation component 530 may include aspects of the compensation components 415 and 420. For example, each compensation component 530 may include a capacitor 440 and transistor 445, as well as a capacitor 455 and transistor 460, as described with reference to FIG. 4. The system 500 may illustrate an example of a control signal component that includes the variable resistor component 470 and the variable capacitor component 480, as described with reference to FIG. 4.

For example, to manage the resistance of the variable resistor component 470, the system 500 may be configured to output a third control signal to the variable resistor component 470. The variable resistor component 470 may include a set of legs, such as a set of resistors 505 (e.g., resistors 505-a, 505-b, and 505-c) coupled in parallel between the ground voltage source 450 and a terminal of the transistor 465-a. Each leg of the variable resistor component 470 may be activated using respective a transistor 510 of a set of transistors 510 (e.g., transistors 510-a, 510-b, and 510-c). Gates of the transistors 510 may be configured to receive the third control signal. In some cases, the third control signal may be binary coded, such that a first state of the third control signal (e.g., a high state, a logic “1”) may activate each transistor 510 and thus may activate each leg of the variable resistor component 470, and a second state of the third control signal (e.g., a low state, a logic “0”) may deactivate each transistor 510 and thus may deactivate each leg of the variable resistor component 470. Alternatively, the third control signal may be configured to have more than two states, such that each state of the third control signal may activate a different combination of the transistors 510, which may allow the variable resistor component 470 to have a corresponding quantity of possible resistances in accordance with the third control signal. By tuning the variable resistor component 470, the system 500 may modify the current delivered to the current mirror 430, and thus tune the delay provided by the compensation components 415 and 420.

Further, to manage the capacitance of the variable capacitor component 480, the system 500 may be configured to output a fourth control signal to the variable capacitor component 480. The variable capacitor component 480 may include a set of legs, such as a set of capacitors 515 (e.g., capacitors 515-a, 515-b, and 515-c) coupled in parallel between the ground voltage source 450 and the gates of the transistors 465-a and 465-b. Each leg of the variable capacitor component 480 may be activated using respective a transistor 520 of a set of transistors 520 (e.g., transistors 520-a, 520-b, and 520-c). Gates of the transistors 520 may be configured to receive the fourth control signal. In some cases, the fourth control signal may be binary coded, such that a first state of the fourth control signal (e.g., a high state, a logic “1”) may activate each transistor 520 and thus may activate each leg of the variable capacitor component 480, and a second state of the fourth control signal (e.g., a low state, a logic “0”) may deactivate each transistor 520 and thus may deactivate each leg of the variable capacitor component 480. Alternatively, the fourth control signal may be configured to have more than two states, such that each state of the fourth control signal may activate a different combination of the transistors 520, which may allow the variable capacitor component 480 to have a corresponding quantity of possible capacitances in accordance with the fourth control signal. By tuning the variable capacitor component 480, the system 500 may modify the resistance-capacitance (RC) value of the variable capacitor component 480 and the resistor 475, and thus tune the frequency range of compensation.

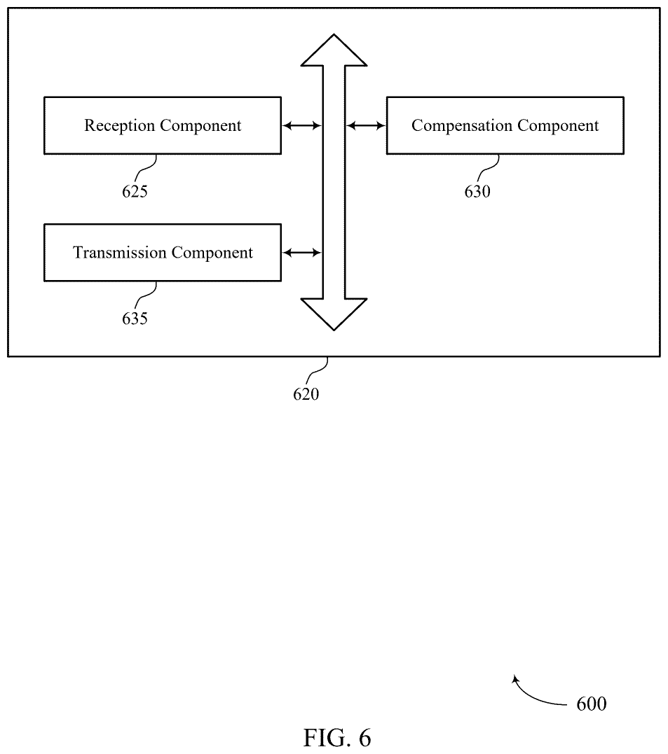

FIG. 6 shows a block diagram 600 of a memory system 620 that supports devices and techniques to modify a clock signal in accordance with examples as disclosed herein. The memory system 620 may be an example of aspects of a memory system as described with reference to FIGS. 1 through 5. The memory system 620, or various components thereof, may be an example of means for performing various aspects of devices and techniques to modify a clock signal as described herein. For example, the memory system 620 may include a reception component 625, a compensation component 630, a transmission component 635, or any combination thereof. Each of these components, or components of subcomponents thereof (e.g., one or more processors, one or more memories), may communicate, directly or indirectly, with one another (e.g., via one or more buses).

The reception component 625 may be configured as or otherwise support a means for receiving, at a clock signal path, a clock signal. The compensation component 630 may be configured as or otherwise support a means for modifying the clock signal using a first compensation circuit coupled with the clock signal path and a current mirror based at least in part on receiving, at the first compensation circuit, a first control signal from the current mirror. In some examples, the compensation component 630 may be configured as or otherwise support a means for modifying the clock signal using a second compensation circuit coupled with the clock signal path and a current mirror based at least in part on receiving, at the second compensation circuit, a second control signal from the current mirror. The transmission component 635 may be configured as or otherwise support a means for transmitting, from the clock signal path, the clock signal modified by the first compensation circuit and the second compensation circuit.

In some examples, the first compensation circuit includes one or more capacitors, each capacitor of the one or more capacitors includes a first terminal that is configured to be coupled with the clock signal path via a transistor and a second terminal coupled with a ground voltage source via a respective variable resistance component.

In some examples, the second compensation circuit includes one or more capacitors, each capacitor of the one or more capacitors includes a first terminal that is configured to be coupled with the clock signal path via a transistor and a second terminal coupled with a supply voltage source via a respective variable resistance component.

In some examples, the described functionality of the memory system 620, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 620, or various components thereof, may be implemented at least in part by instructions (e.g., stored in memory, non-transitory computer-readable medium) executable by such at least one processor.

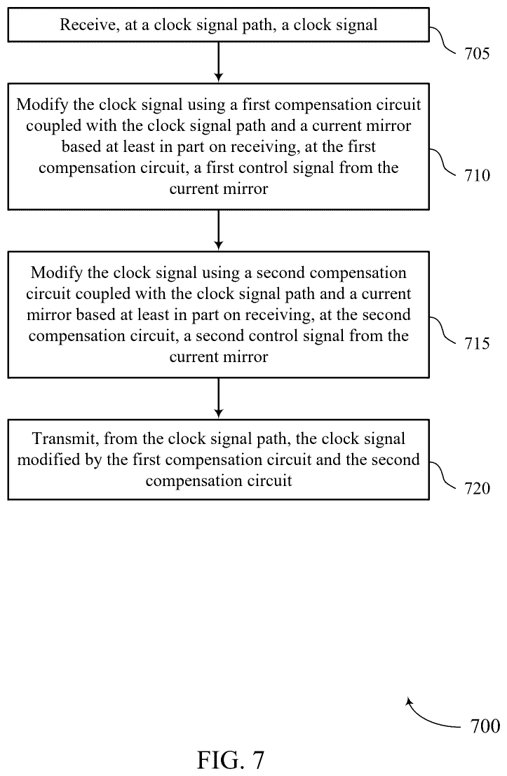

FIG. 7 shows a flowchart illustrating a method 700 that supports devices and techniques to modify a clock signal in accordance with examples as disclosed herein. The operations of method 700 may be implemented by a memory system or its components as described herein. For example, the operations of method 700 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 705, the method may include receiving, at a clock signal path, a clock signal. In some examples, aspects of the operations of 705 may be performed by a reception component 625 as described with reference to FIG. 6.

At 710, the method may include modifying the clock signal using a first compensation circuit coupled with the clock signal path and a current mirror based at least in part on receiving, at the first compensation circuit, a first control signal from the current mirror. In some examples, aspects of the operations of 710 may be performed by a compensation component 630 as described with reference to FIG. 6.

At 715, the method may include modifying the clock signal using a second compensation circuit coupled with the clock signal path and a current mirror based at least in part on receiving, at the second compensation circuit, a second control signal from the current mirror. In some examples, aspects of the operations of 715 may be performed by a compensation component 630 as described with reference to FIG. 6.

At 720, the method may include transmitting, from the clock signal path, the clock signal modified by the first compensation circuit and the second compensation circuit. In some examples, aspects of the operations of 720 may be performed by a transmission component 635 as described with reference to FIG. 6.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving, at a clock signal path, a clock signal; modifying the clock signal using a first compensation circuit coupled with the clock signal path and a current mirror based at least in part on receiving, at the first compensation circuit, a first control signal from the current mirror; modifying the clock signal using a second compensation circuit coupled with the clock signal path and a current mirror based at least in part on receiving, at the second compensation circuit, a second control signal from the current mirror; and transmitting, from the clock signal path, the clock signal modified by the first compensation circuit and the second compensation circuit.

Aspect 2: The method, apparatus, or non-transitory computer-readable medium of aspect 1, where the first compensation circuit includes one or more capacitors and each capacitor of the one or more capacitors includes a first terminal that is configured to be coupled with the clock signal path via a transistor and a second terminal coupled with a ground voltage source via a respective variable resistance component.

Aspect 3: The method, apparatus, or non-transitory computer-readable medium of any of aspects 1 through 2, where the second compensation circuit includes one or more capacitors and each capacitor of the one or more capacitors includes a first terminal that is configured to be coupled with the clock signal path via a transistor and a second terminal coupled with a supply voltage source via a respective variable resistance component.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 4: An apparatus, including: a clock signal path configured to communicate a clock signal, the clock signal path including an input, an output, and one or more components associated with delaying the clock signal between the input and the output; and a delay adjustment circuit configured to modify the clock signal at the output of the clock signal path with the clock signal at the input of the clock signal path, the delay adjustment circuit including: a first compensation circuit coupled with the clock signal path, the first compensation circuit configured to modify a delay of the clock signal based at least in part on a first control signal; a second compensation circuit coupled with the clock signal path, the second compensation circuit configured to modify the delay of the clock signal based at least in part on a second control signal; and a current mirror coupled with a supply voltage source, the first compensation circuit, and the second compensation circuit, the current mirror configured to output the first control signal to the first compensation circuit and output the second control signal to the second compensation circuit.

Aspect 5: The apparatus of aspect 4, where the first compensation circuit includes one or more capacitors, each capacitor of the one or more capacitors includes a first terminal that is configured to be coupled with the clock signal path via a transistor and a second terminal coupled with a ground voltage source via a respective variable resistance component.

Aspect 6: The apparatus of aspect 5, where each variable resistance component includes a respective gate configured to receive the first control signal from the current mirror, a respective resistance of each variable resistance component is based at least in part on the first control signal.

Aspect 7: The apparatus of any of aspects 5 through 6, where each of the one or more capacitors includes a respective nMOS capacitor.

Aspect 8: The apparatus of any of aspects 5 through 7, where each variable resistance component includes a respective nMOS transistor.

Aspect 9: The apparatus of any of aspects 4 through 8, where the second compensation circuit includes one or more capacitors, each capacitor of the one or more capacitors includes a first terminal coupled with the clock signal path and a second terminal coupled with the supply voltage source via a respective variable resistance component.

Aspect 10: The apparatus of aspect 9, where each variable resistance component includes a respective gate configured to receive the second control signal from the current mirror, a respective resistance of each variable resistance component is based at least in part on the second control signal.

Aspect 11: The apparatus of any of aspects 9 through 10, where each of the one or more capacitors is a respective pMOS capacitor.

Aspect 12: The apparatus of any of aspects 9 through 11, where each variable resistance component is a respective pMOS transistor.

Aspect 13: The apparatus of any of aspects 4 through 12, further including: a control signal component coupled with the first compensation circuit, the second compensation circuit, and the current mirror, the control signal component configured to modify the first control signal and the second control signal to reduce variations in the delay based at least in part on variations a voltage of the supply voltage source.

Aspect 14: The apparatus of aspect 13, where the control signal component includes a variable resistor coupled in parallel with a variable capacitor.

Aspect 15: The apparatus of aspect 14, where: the variable resistor includes a plurality of transistors, each transistor of the plurality of transistors configured to be activated based at least in part on a third control signal; and the variable capacitor includes a plurality of capacitors, each capacitor of the plurality of capacitors configured to be activated based at least in part on a fourth control signal.

Aspect 16: The apparatus of any of aspects 4 through 15, where each component associated with delaying the clock signal includes a respective inverter.

An apparatus is described. The following provides an overview of aspects of the apparatus as described herein:

Aspect 17: An apparatus, including: a clock signal path configured to communicate a clock signal, the clock signal path including an input, an output, and one or more components associated with delaying the clock signal between the input and the output; one or more first capacitors, each first capacitor of the one or more first capacitors coupled between the clock signal path and a respective first transistor of one or more first transistors; one or more second capacitors, each second capacitor of the one or more second capacitors coupled between the clock signal path and a respective second transistor of one or more second transistors; and a current mirror configured to output a first control signal to the one or more first transistors and output a second control signal to the one or more second transistors.

Aspect 18: The apparatus of aspect 17, where each first transistor of the one or more first transistors includes a respective first terminal coupled with the respective first capacitor of the one or more first capacitors, a respective second terminal coupled with a ground voltage source, and a respective gate coupled with the current mirror.

Aspect 19: The apparatus of any of aspects 17 through 18, where each second transistor of the one or more second transistors includes a respective first terminal coupled with the respective second capacitor of the one or more second capacitors, a respective second terminal coupled with a supply voltage source, and a respective gate coupled with the current mirror.

Aspect 20: The apparatus of any of aspects 17 through 19, where each first capacitor of the one or more first capacitors includes a respective nMOS capacitor and each second capacitor of the one or more second capacitors includes a respective pMOS capacitor.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a clock signal path configured to communicate a clock signal, the clock signal path comprising an input, an output, and one or more components associated with delaying the clock signal between the input and the output; and
a delay adjustment circuit configured to modify the clock signal at the output of the clock signal path with the clock signal at the input of the clock signal path, the delay adjustment circuit comprising:
a first compensation circuit coupled with the clock signal path, the first compensation circuit configured to modify a delay of the clock signal based at least in part on a first control signal;
a second compensation circuit coupled with the clock signal path, the second compensation circuit configured to modify the delay of the clock signal based at least in part on a second control signal; and
a current mirror coupled with a supply voltage source, the first compensation circuit, and the second compensation circuit, the current mirror configured to output the first control signal to the first compensation circuit and output the second control signal to the second compensation circuit.

2. The apparatus of claim 1, wherein the first compensation circuit comprises one or more capacitors, each capacitor of the one or more capacitors comprises a first terminal that is configured to be coupled with the clock signal path via a transistor and a second terminal coupled with a ground voltage source via a respective variable resistance component.

3. The apparatus of claim 2, wherein each variable resistance component comprises a respective gate configured to receive the first control signal from the current mirror, a respective resistance of each variable resistance component is based at least in part on the first control signal.

4. The apparatus of claim 2, wherein each of the one or more capacitors comprises a respective nMOS capacitor.

5. The apparatus of claim 2, wherein each variable resistance component comprises a respective nMOS transistor.

6. The apparatus of claim 1, wherein the second compensation circuit comprises one or more capacitors, each capacitor of the one or more capacitors comprises a first terminal coupled with the clock signal path and a second terminal coupled with the supply voltage source via a respective variable resistance component.

7. The apparatus of claim 6, wherein each variable resistance component comprises a respective gate configured to receive the second control signal from the current mirror, a respective resistance of each variable resistance component is based at least in part on the second control signal.

8. The apparatus of claim 6, wherein each of the one or more capacitors is a respective pMOS capacitor.

9. The apparatus of claim 6, wherein each variable resistance component is a respective pMOS transistor.

10. The apparatus of claim 1, further comprising:
a control signal component coupled with the first compensation circuit, the second compensation circuit, and the current mirror, the control signal component configured to modify the first control signal and the second control signal to reduce variations in the delay based at least in part on variations a voltage of the supply voltage source.

11. The apparatus of claim 10, wherein the control signal component comprises a variable resistor coupled in parallel with a variable capacitor.

12. The apparatus of claim 11, wherein:
the variable resistor comprises a plurality of transistors, each transistor of the plurality of transistors configured to be activated based at least in part on a third control signal; and
the variable capacitor comprises a plurality of capacitors, each capacitor of the plurality of capacitors configured to be activated based at least in part on a fourth control signal.

13. The apparatus of claim 1, wherein each component associated with delaying the clock signal comprises a respective inverter.

14. An apparatus, comprising:
a clock signal path configured to communicate a clock signal, the clock signal path comprising an input, an output, and one or more components associated with delaying the clock signal between the input and the output;
one or more first capacitors, each first capacitor of the one or more first capacitors coupled between the clock signal path and a respective first transistor of one or more first transistors;
one or more second capacitors, each second capacitor of the one or more second capacitors coupled between the clock signal path and a respective second transistor of one or more second transistors; and
a current mirror configured to output a first control signal to the one or more first transistors and output a second control signal to the one or more second transistors.

15. The apparatus of claim 14, wherein each first transistor of the one or more first transistors comprises a respective first terminal coupled with the respective first capacitor of the one or more first capacitors, a respective second terminal coupled with a ground voltage source, and a respective gate coupled with the current mirror.

16. The apparatus of claim 14, wherein each second transistor of the one or more second transistors comprises a respective first terminal coupled with the respective second capacitor of the one or more second capacitors, a respective second terminal coupled with a supply voltage source, and a respective gate coupled with the current mirror.

17. The apparatus of claim 14, wherein each first capacitor of the one or more first capacitors comprises a respective nMOS capacitor and each second capacitor of the one or more second capacitors comprises a respective pMOS capacitor.

18. A method, comprising:
receiving, at a clock signal path, a clock signal;
modifying the clock signal using a first compensation circuit coupled with the clock signal path and a current mirror based at least in part on receiving, at the first compensation circuit, a first control signal from the current mirror;
modifying the clock signal using a second compensation circuit coupled with the clock signal path and a current mirror based at least in part on receiving, at the second compensation circuit, a second control signal from the current mirror; and
transmitting, from the clock signal path, the clock signal modified by the first compensation circuit and the second compensation circuit.

19. The method of claim 18, wherein the first compensation circuit comprises one or more capacitors, each capacitor of the one or more capacitors comprises a first terminal that is configured to be coupled with the clock signal path via a transistor and a second terminal coupled with a ground voltage source via a respective variable resistance component.

20. The method of claim 18, wherein the second compensation circuit comprises one or more capacitors, each capacitor of the one or more capacitors comprises a first terminal that is configured to be coupled with the clock signal path via a transistor and a second terminal coupled with a supply voltage source via a respective variable resistance component.
